(19) United States
(12) Patent Application Publication
(10) Pub. No.: US 2026/0221170 A1
(43) Pub. Date: Jul. 30, 2026

(54) DRIVER AMPLIFIER INCLUDING PARALLEL-INTEGRATED FLIPPED VOLTAGE FOLLOWER AND SOURCE FOLLOWER

(71) Applicant: QUALCOMM Incorporated, San Diego, CA (US)

(72) Inventors: Bharadvaj BHAMIDIPATI, San Diego, CA (US); Andrew WEIL, San Diego, CA (US); Jaswinder SINGH, San Diego, CA (US)

(21) Appl. No.: 18/962,942

(22) Filed: Nov. 27, 2024

(51) Int. Cl. G11C 5/14; H03F 3/45

(52) U.S. Cl. CPC G11C 5/148; H03F 3/45179; H03F 3/45475; H03F 2200/69

(57) ABSTRACT

An apparatus, including: a first amplifier including: a flipped voltage follower, and a source follower coupled in parallel with the flipped voltage follower; and a load coupled to an output of the first amplifier.

### FIELD

This disclosure relates generally to load driver amplifiers, and in particular, to a driver amplifier including parallel-integrated flipped voltage follower and source follower.

### BACKGROUND

In some applications, a load coupled to an output of a driver amplifier may exhibit wide variations in its current demand. Such wide-varying current may require the driver amplifier to supply significant current to and/or draw significant current from the load. To effectively meet the current demand from such a load, it may be desirable for the output impedance of the driver amplifier to remain significantly low in both situations of supplying current to and drawing current from the load.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus includes a first amplifier including: a flipped voltage follower, and a source follower coupled in parallel with the flipped voltage follower; and a load coupled to an output of the first amplifier.

Another aspect of the disclosure relates to a method of driving a load. The method includes supplying a first current to the load using a flipped voltage follower; and drawing a second current from the load using a source follower.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example load (e.g., memory) driving circuit in accordance with an aspect of the disclosure.

FIG. 2 illustrates a block diagram of another example load (e.g., memory) driving circuit in accordance with another aspect of the disclosure.

FIG. 3 illustrates a schematic diagram of an example PFET-based source follower (SF) in accordance with another aspect of the disclosure.

FIG. 4 illustrates a schematic diagram of an example NFET-based source follower (SF) in accordance with another aspect of the disclosure.

FIG. 5 illustrates a schematic diagram of an example PFET-based flipped voltage follower in accordance with another aspect of the disclosure.

FIG. 6 illustrates a schematic diagram of an example load driver amplifier in accordance with another aspect of the disclosure.

FIG. 7 illustrates a schematic diagram of another example load driver amplifier in accordance with another aspect of the disclosure.

FIG. 8 illustrates a flow diagram of an example method of driving a load in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter may not be exact as indicated but accounts for some variation due to specified tolerances.

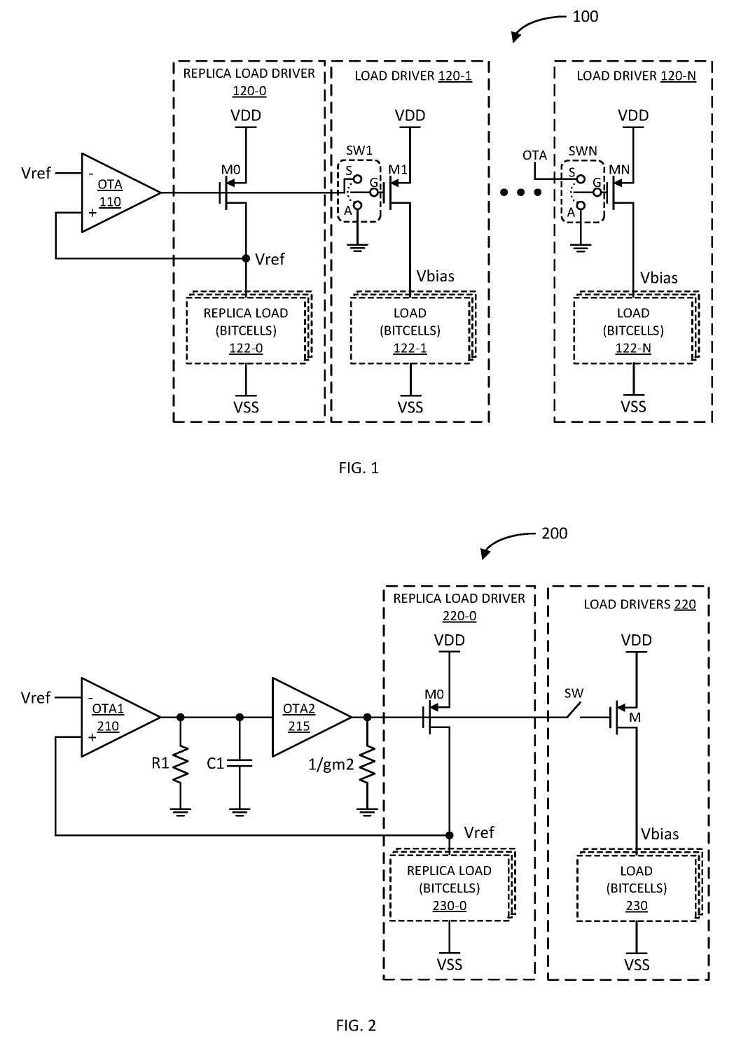

FIG. 1 illustrates a block diagram of an example load (e.g., memory) driving circuit 100 in accordance with an aspect of the disclosure. The load driving circuit 100 includes an operational transconductance amplifier (OTA) 110, a replica load driver 120-0, and a set of load drivers 120-1 to 120-N. The OTA 110 includes a first (e.g., negative) input configured to receive a reference voltage Vref, a second (e.g., positive) input, and an output.

The replica load driver 120-0 includes a p-channel field effect transistor (PFET) M0 coupled in series with a replica load 122-0 (e.g., a set of replica bitcells or memory cells) between an upper voltage rail VDD and a lower voltage rail VSS (e.g., ground). That is, the PFET M0 includes a source coupled to the upper voltage rail VDD, a gate coupled to the output of the OTA 110, and a drain coupled to the second (e.g., positive) input of the OTA 110. The replica load 122-0 is coupled between the drain of the PFET M0 and the lower voltage rail VSS.

The set of load drivers 120-1 to 120-N includes a set of switching devices SW1 to SWN and a set of PFETs M1 to MN, respectively. That is, the set of PFETs M1 to MN are coupled in series with the set of loads (e.g., bitcells or memory cells) 122-1 to 122-N between the upper voltage rail VDD and the lower voltage rail VSS, respectively. That is, the set of PFETs M1 to MN include respective sources coupled to the upper voltage rail VDD. The set of loads 122-1 to 122-N are coupled between drains of the set of PFETs M1 to MN and the lower voltage rail VSS, respectively.

The set of switching devices SW1 to SWN, which may each be implemented as a single-pole-double-throw (SPDT) switching device, include a set of pole terminals (G), a first set of throw terminals (S), and a second set of throw terminals (A), respectively. The pole terminals (G) of the set of switching devices SW1 to SWN are coupled to gates of the set of PFETs M1 to MN, respectively. The first set of throw terminals (S) are coupled to the output of the OTA 110. The second set of throw terminals (A) are coupled to the lower voltage rail VSS and/or ground.

The set of loads (e.g., bitcells) 122-1 to 122-N may be set to an active (A) (e.g., operational) mode or a sleep (S) (e.g., low power) mode. One solution for selectively setting the loads (e.g., bitcells) 122-1 to 122-N between active (A) mode or sleep (S) mode is to fully turn on or off the corresponding PFET, respectively. This may be accomplished by coupling the gate(s) of the PFET(s) associated with the selected load(s) (e.g., bitcell(s)) to the lower voltage rail VSS or ground (e.g., turning on the corresponding PFET) to set the selected load(s) to active (A) mode, or to the upper voltage rail VDD (e.g., turning off the corresponding PFET) to set the selected load(s) to sleep (S) mode. A drawback of this approach is that data stored in the selected bitcells may be lost during sleep (S) mode, which may require storing the data elsewhere prior to placing the bitcells in sleep (S) mode, and then rewriting the data back into the selected bitcells when it is needed. The process of storing the data elsewhere and rewriting the data back into the selected bitcells may consume more power than simply maintaining the bitcells in active (A) mode.

Another solution for selectively setting loads (e.g., bitcells) 122-1 to 122-N between active (A) mode or sleep (S) mode is to lower the supply voltage VDD associated with the selected load(s) (e.g., bitcells). This approach is sometimes referred to as Automatic Power Modulation (APM). A drawback of this approach is that to access the selected loads (e.g., bitcells) after being placed in sleep (S) mode, the supply voltage VDD has to be brought up, which causes charging of the selected (e.g., bitcells), which consumes power.

Accordingly, the approach shown in the example of FIG. 1 is referred to as Voltage Data Reduction (VDR), where the set of PFETs M1 and MN are operated as current sources instead of switches. With regard to active (A) mode, a selected subset of the loads (e.g., bitcells) 122-1 to 122-N may be placed in active (A) mode by coupling the gates of the selected PFETs M1 to MN to the lower voltage rail VSS or ground via the switching devices SW1 to SWn to fully turn on the selected PFETs M1 to MN, respectively. In active (A) mode, the voltage Vbias provided to the selected subset of loads (e.g., bitcells) is substantially the supply voltage at the upper voltage rail VDD (e.g., Vbias=VDD.

With regard to sleep (S) mode, a selected subset of the loads (e.g., bitcells) 122-1 to 122-N may be placed in sleep (S) mode by coupling the gates of the selected PFETs M1 to MN to the output of the OTA 110 via the switching devices SW1 to SWN to control the selected PFETs M1 to MN as current sources, respectively. Through feedback operation with respect to the replica load driver 120-0, which causes the replica load (e.g., replica bitcells) 122-0 to receive a bias voltage substantially equal to the reference voltage Vref, the selected subset of the loads (e.g.., bitcells) 122-1 to 122-N placed in sleep (S) mode receive a bias voltage Vbias being substantially equal to the reference voltage (e.g., Vbias=Vref). The reference voltage Vref is selected to cause the corresponding PFETs to generate a small amount of current to save power during sleep (S) mode, while providing a bias voltage Vbias to the selected subset of the loads (e.g.., bitcells) 122-1 to 122-N to retain the data.

Further, in accordance with sleep (S) mode, the biasing of the selected PFETs M1 to MN also accounts for variation in process voltage temperature (PVT). This is because the replica load driver 120-0 is affected in substantially the same manner as the set of load drivers 120-1 to 120-N with variation in PVT. Thus, for different process corners, the reference voltage Vref and the bias voltage Vbias in sleep (S) mode vary substantially the same. Similarly, with variation in the supply voltage VDD, the reference voltage Vref and the bias voltage Vbias in sleep (S) mode vary substantially the same. Likewise, for variation in the temperature, the reference voltage Vref and the bias voltage Vbias in sleep (S) mode vary substantially the same.

An issue with the load (e.g., memory) driving circuit 100 is that switching between active (A) mode and sleep (S) mode for a large set of loads (e.g., bitcells) typically produces large transients. For example, when switching a large set of loads (e.g., bitcells) from active (A) mode to sleep (S) mode, a large rising current transient is produced as more PFETs are coupled to the output of the OTA 110. Conversely, when switching a large set of loads (e.g., bitcells) from sleep (S) mode to active (M) mode, a large falling current transient is produced as more PFETs are decoupled from the output of the OTA 110. These transients may destabilize the control loop effectuated by the OTA 110 and the replica load driver 120-0.

FIG. 2 illustrates a block diagram of another example load (e.g., memory) driving circuit 200 in accordance with another aspect of the disclosure. The load (e.g., memory) driving circuit 200 is similar to that of load (e.g., memory) driving circuit 100 including a replica driver 220-0, and a set of load drivers, collectively identified with reference number 220, including a set of switching devices SW, and a set of PFETs M coupled to a set of loads (e.g., bitcells) 230, as previously discussed. In contrast, the bias voltage Vbias control circuit of load (e.g., memory) driving circuit 200 is different than the bias voltage Vbias control circuit of load (e.g., memory) driving circuit 100.

More specifically, the bias voltage Vbias control circuit of load (e.g., memory) driving circuit 200 includes a first operational transconductance amplifier (OTA1) 210 cascaded with a second OTA2 215. The bias voltage Vbias control circuit may further include a shunt resistor R1 and a shunt capacitor C1 coupled to an output of the first OTA1 210 for loop stability (e.g., for setting the pole of the first OTA1210). Similarly, the first OTA1 includes a first (e.g., negative) input configured to receive a reference voltage, a second (e.g., positive) input coupled to the node between the replica PFET M0 and the replica load (e.g., bitcells) 230-0. The output impedance of the second OTA2215 is represented as a shunt resistor 1/gm2 coupled to the output of the second OTA2215.

The first OTA1210 provides the primary low frequency or pole control of the bias voltage Vbias. The second OTA2215 deals with fast voltage/current transients generated by switching of the loads (e.g., bitcells) between active (A) mode and sleep (S) mode, as previously discussed. In this regards, it is preferred that the second OTA2215 have a low output impedance 1/gm2 to source and sink the transient currents associated with the switching from active (A) mode to sleep (S) mode and switching from sleep (S) mode to active (A) mode, respectively. Further, it is also preferred that the pole of the second OTA2215 is high enough in frequency that it does not encroach on the low frequency pole of the first OTA1210.

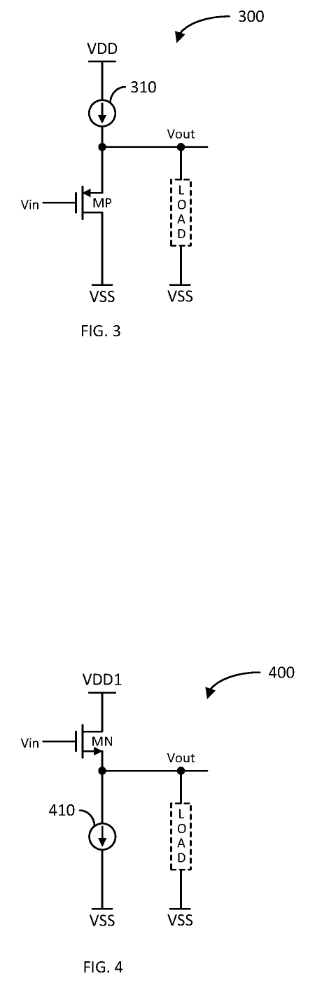

FIG. 3 illustrates a schematic diagram of an example PFET-based source follower (SF) 300 in accordance with another aspect of the disclosure. The source follower 300 may be an example implementation of the second OTA2215 of load (e.g., memory) driving circuit 200.

In particular, the source follower 300 includes a current source 310 coupled in series with a PFET MP between an upper voltage rail VDD and a lower voltage rail VSS (e.g., ground). That is, the current source 310 is coupled between the upper voltage rail VDD and a source of the PFET MP. The PFET MP includes a gate configured to receive an input signal Vin (e.g., generated by the first OTA1210), and a drain coupled to the lower voltage rail VSS. The source follower 300 is configured to generate an output voltage Vout for applying to the gate of the replica PFET M0 and the gates of selected ones (in sleep mode (S)) of the set of PFETs M of load (e.g., memory) driving circuit 200 (represented as a load coupled between the output (e.g., at source of PFET MP) of the source follower 300 and the lower voltage rail VSS.

A drawback of the PFET-based source follower 300 is that it may be required to source a relatively large current (e.g., one (1) milli Amp (mA)), whereas a more practical current source 310 may supply a current of 10 micro Amps (μA). However, the PFET MP may be sized to sink a relatively large current (e.g., 1mA). Thus, the source follower 300 may be practical to sink significant transient current, but not source significant transient current. Or said differently, the output impedance of the source follower 300 is relatively high for sourcing current and relatively low for sinking current. As previously discussed, it is desirable for the source follower to have a low output impedance such that its pole does not encroach on the pole of the first OTA1210 of load (e.g., memory) driving circuit 200.

FIG. 4 illustrates a schematic diagram of another example NFET-based source follower (SF) 400 in accordance with another aspect of the disclosure. The source follower 400 may be an example implementation of the second OTA2215 of load (e.g., memory) driving circuit 200.

In particular, the source follower 400 includes an n-channel field effect transistor (NFET) MN coupled in series with a current source 410 between an upper voltage rail VDD1 and a lower voltage rail VSS (e.g., ground). That is, the NFET MN includes a drain coupled to the upper voltage rail VDD1, and a gate configured to receive an input voltage (signal) Vin (e.g., generated by the first OTA1 210). The source follower 400 is configured to generate an output voltage Vout for applying to the gate of the replica PFET M0 and the gates of selected ones (e.g., in sleep (S) mode) of the set of PFETs M of load (e.g., memory) driving circuit 200 (represented as a load coupled between the output (e.g., at the source of NFET MN) of the source follower 400 and the lower voltage rail VSS.

A drawback of the NFET-based source follower 400 is that it needs a lot of headroom to suitably operate, which may require a supply voltage VDD1 higher than the supply voltage VDD provided to the replica load driver 220-0 and set of load drivers 220 (e.g., VDD1>VDD). A consequence of this drawback is that the higher supply voltage VDD1 may require overvoltage protection for the NFET MN and the current source 410, which may the circuitry of the NFET-based source follower 400.

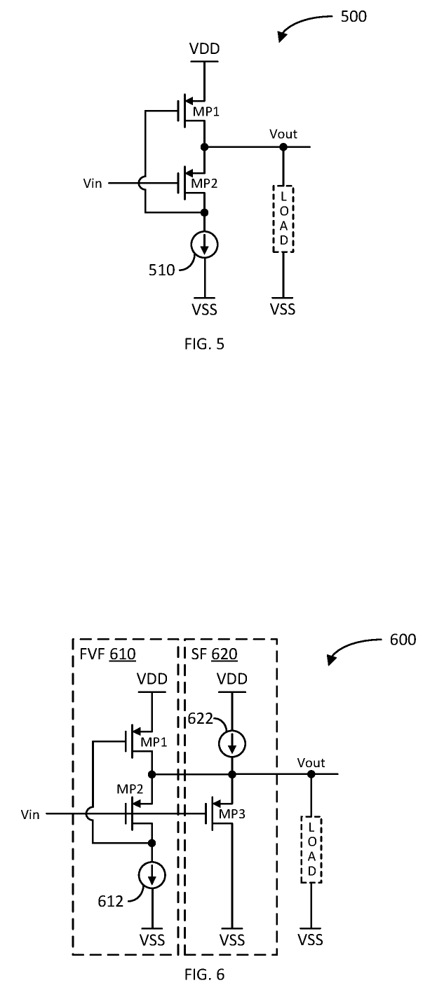

FIG. 5 illustrates a schematic diagram of an example PFET-based flipped voltage follower (FVF) 500 in accordance with another aspect of the disclosure. The PFET-based flipped voltage follower 500 may be an example implementation of the second OTA2215 of load (e.g., memory) driving circuit 200.

In particular, the PFET-based flipped voltage follower 500 includes a first PFET MP1, a second PFET MP2, and a current source 510 coupled in series between an upper voltage rail VDD and a lower voltage rail VSS (e.g., ground). That is, the first PFET MP1 includes a source coupled to the upper voltage rail VDD, a gate coupled to a drain of the second PFET MP2, and a drain coupled to a source of the second PFET MP2. The second PFET MP2 includes a gate configured to receive an input voltage (signal) Vin. The current source 510 is coupled between the drain of the second PFET MP2 and the lower voltage rail VSS. The PFET-based flipped voltage follower 500 is configured to generate an output voltage (signal) Vout for applying to the gate of the replica PFET M0 and the gates of selected ones (e.g., in sleep (S) mode) of the set of PFETs M of load (e.g., memory) driving circuit 200 (represented as a load coupled between the output (e.g., at the drain and source of the PFETs MP1 and MP2, respectively) of the PFET-based flipped voltage follower 500 and the lower voltage rail VSS.

A drawback of the PFET-based flipped voltage follower 500 is that it may be required to sink a relatively large current (e.g., 1mA), whereas a more practical current source 510 may sink a current of 10μA. However, via a relatively large gain provided by the feedback loop configuration of the first PFET MP1 and the second PFET MP2 (e.g., the drain of the second PFET MP2 coupled to the gate of the first PFET MP1), the PFET-based flipped voltage follower 500 may be able to source a relatively large current (e.g., 1mA). Thus, the PFET-based flipped voltage follower 500 may be practical to source significant transient current, but not sink significant transient current. Or said differently, the output impedance of the PFET-based flipped voltage follower 500 is relatively low for sourcing current and relatively high for sinking current.

FIG. 6 illustrates a schematic diagram of an example load driver amplifier 600 in accordance with another aspect of the disclosure. The load driver amplifier 600 may be an example implementation of the second OTA2215 of load (e.g., memory) driving circuit 200. The load driver amplifier 600 includes a PFET-based flipped voltage follower (FVF) 610 coupled in parallel with a PFET-based source follower (SF) 620 between an upper voltage rail VDD and a lower voltage rail VSS (e.g., ground.

In particular, the PFET-based flipped voltage follower 610 includes a first PFET MP1, a second PFET MP2, and a first current source 612 coupled in series between the upper voltage rail VDD and the lower voltage rail VSS. That is, the first PFET MP1 includes a source coupled to the upper voltage rail VDD, a gate coupled to a drain of the second PFET MP2, and a drain coupled to a source of the second PFET MP2. The second PFET MP2 includes a gate configured to receive an input voltage (signal) Vin. The first current source 612 is coupled between the drain of the second PFET MP2 and the lower voltage rail VSS.

The PFET-based source follower 620 includes a second current source 622 coupled in series with a third PFET MP3 between the upper voltage rail VDD and the lower voltage rail VSS. That is, the second current source 622 is coupled between the upper voltage rail VDD and a source of the third PFET MP3. The source of the third PFET MP3 is coupled to the drain of the first PFET MP1 and the source of the second PFET MP2, all of which serve as an output of the load driver amplifier 600. The third PFET MP3 includes a gate coupled to the gate of the second PFET MP2 (also configured to receive the input signal Vin). The third PFET MP3 includes a drain coupled to the lower voltage rail VSS.

The load driver amplifier 600 is configured to generate an output voltage (signal) Vout for driving a load (e.g., the gate of the replica PFET M0 and gates of selected ones (e.g., in sleep (S) mode) of the set of PFETs M of load (e.g., memory) driving circuit 200 (represented as a load coupled between the output of the load driver amplifier 600 and the lower voltage rail VSS).

The load driver amplifier 600 exhibits the benefits of both the PFET-based flipped voltage follower 610 and the PFET-based source follower 620. That is, via its relatively large gain provided by the feedback loop configuration of the first PFET MP1 and the second PFET MP2 (e.g., the drain of the second PFET MP2 is coupled to the gate of the first PFET MP1), the PFET-based flipped voltage follower 610 may be able to source a relatively large current (e.g., 1mA). With regard to the PFET-based source follower 620, the third PFET MP3 may be sized to sink a relatively large current (e.g., 1mA). Thus, the PFET-based source follower 620 may be practical to sink significant transient current. In summary, the output impedance of the load driver amplifier 600 is relatively low for both sourcing and sinking current. This is highly desirable as the low output impedance results in a pole for the load driver amplifier 600 that may not encroach on the pole of the first OTA1210 of load (e.g., memory) driving circuit 200.

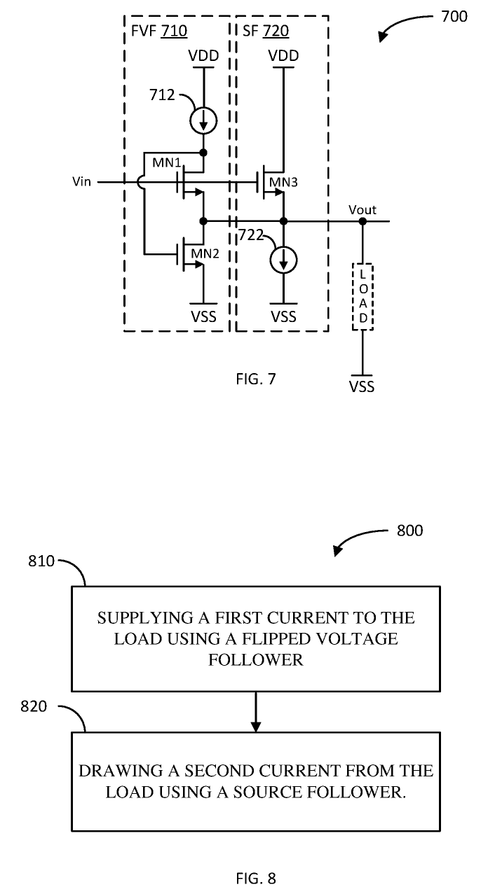

FIG. 7 illustrates a schematic diagram of another example load driver amplifier 700 in accordance with another aspect of the disclosure. The load driver amplifier 700 may be an NFET version of the load driver amplifier 600. The load driver amplifier 700 includes an NFET-based flipped voltage follower (FVF) 710 coupled in parallel with an NFET-based source follower (SF) 720 between an upper voltage rail VDD and a lower voltage rail VSS (e.g., ground.

In particular, the NFET-based flipped voltage follower 710 includes a first current source 712, a first NFET MN1, and a second NFET MN2 coupled in series between the upper voltage rail VDD and the lower voltage rail VSS. That is, the first current source 712 is coupled between the upper voltage rail VDD and the drain of the first NFET MN1. The drain of the first NFET MN1 is coupled to a gate of the second NFET MN2 to effectuate a feedback loop configuration. The first NFET MN1 includes a gate configured to receive an input voltage (signal) Vin. The first NFET MN1 includes a source coupled to a drain of the second NFET MN2. The second NFET MN2 includes a source coupled to the lower voltage rail VSS.

The source follower 720 includes a third NFET MN3 coupled in series with a second current source 722 between the upper voltage rail VDD and the lower voltage rail VSS. That is, the third NFET MN3 includes a drain coupled to the upper voltage rail VDD. The third NFET MN3 includes a gate coupled to the gate coupled of the first NFET MN1 (also configured to receive the input signal Vin). The third NFET MN3 includes a source coupled to the source of the first NFET MN1 and the drain of the second NFET MN2, all of which serve as an output of the load driver amplifier 700. The second current source 722 is coupled between the output of the load driver amplifier 700 and the lower voltage rail VSS. A load may be coupled between the output of the load driver amplifier 700 and the lower voltage rail VSS.

The load driver amplifier 700 exhibits the benefits of both the NFET-based flipped voltage follower 710 and the NFET-based source follower 720. That is, via its relatively large gain provided by the loop configuration of the first NFET MN1 and the second NFET MN2 (e.g., the drain of the first NFET MN1 is coupled to the gate of the second NFET MN2), the NFET-based flipped voltage follower 710 may be able to sink a relatively large current (e.g., 1mA). With regard to the NFET-based source follower 720, the third NFET MN3 may be sized to source a relatively large current (e.g., 1mA). Thus, the NFET-based source follower 720 may be practical to source significant transient current. In summary, the output impedance of the load driver amplifier 700 is relatively low for both sourcing and sinking current.

FIG. 8 illustrates a flow diagram of an example method 800 of driving a load in accordance with another aspect of the disclosure. The method 800 includes supplying a first current to the load using a flipped voltage follower (block 810). The method 800 further includes drawing a second current from the load using a source follower (block 820).

The following provides an overview of aspects of the present disclosure:

Aspect 1: An apparatus, comprising: a first amplifier including: a flipped voltage follower, and a source follower coupled in parallel with the flipped voltage follower; and a first load coupled to an output of the first amplifier.

Aspect 2: The apparatus of aspect 1, wherein the flipped voltage follower comprises: a first p-channel field effect transistor (PFET) including a source coupled to an upper voltage rail; a second PFET including a source coupled to a drain of the first PFET, a gate configured to receive an input signal, and a drain coupled to a gate of the first PFET, wherein the drain of the first PFET and the source of the second PFET serve as the output of the first amplifier; and a first current source coupled between a drain of the second PFET and a lower voltage rail.

Aspect 3: The apparatus of aspect 2, wherein the source follower comprises: a second current source coupled between the upper voltage rail and the output of the first amplifier; and a third PFET including a source coupled to the output of the first amplifier, a gate coupled to the gate of the second PFET, and a drain coupled to the lower voltage rail.

Aspect 4: The apparatus of aspect 1, wherein the flipped voltage follower comprises: a first current source; a first NFET, wherein the first current source is coupled between an upper voltage rail and a drain of the first NFET; and a second NFET including a drain coupled to a source of the first NFET, a gate coupled to the drain of the first NFET, and a source coupled to a lower voltage rail, wherein the source of the first NFET and the drain of the second NFET serve as the output of the first amplifier.

Aspect 5: The apparatus of aspect 4, wherein the source follower comprises: a third NFET including a drain coupled to the upper voltage rail, a gate coupled to the gate of the first NFET, and a source coupled to the output of the first amplifier; and a second current source coupled between the output of the first amplifier and the lower voltage rail.

Aspect 6: The apparatus of any one of aspects 1-5, wherein the first load comprises a load driver.

Aspect 7: The apparatus of aspect 6, wherein the load driver comprises: a p-channel field effect transistor (PFET) including a source coupled to an upper voltage rail, and a gate coupled to the output of the first amplifier, and a second load coupled between a drain of the PFET and a lower voltage rail.

Aspect 8: The apparatus of aspect 7, further comprising a second amplifier including a first input configured to receive a reference voltage, a second input coupled to a node between the PFET and the second load, and an output coupled to an input of the first amplifier.

Aspect 9: The apparatus of aspect 7 or 8, wherein the second load comprises a set of bitcells.

Aspect 10: The apparatus of any one of aspects 1-4, wherein the first load comprises: a replica load driver; and a set of load drivers.

Aspect 11: The apparatus of aspect 10, wherein the replica load driver comprises: a replica p-channel field effect transistor (PFET) including a source coupled to an upper voltage rail, and a gate coupled to the output of the first amplifier, and a replica load coupled between a drain of the replica PFET and a lower voltage rail.

Aspect 12: The apparatus of aspect 11, further comprising a second amplifier including a first input configured to receive a reference voltage, a second input coupled to a node between the replica PFET and the replica load, and an output coupled to an input of the first amplifier.

Aspect 13: The apparatus of aspect 12, wherein each of the set of load drivers comprises: a PFET including a source coupled to the upper voltage rail; a second load coupled between a drain of the PFET and the lower voltage rail; and a switching device including a pole terminal coupled to a gate of the PFET, a first throw terminal coupled to the output of the first amplifier, and a second throw terminal coupled to the lower voltage rail or ground.

Aspect 14: The apparatus of aspect 13, wherein: the replica load comprises a set of replica bitcells; and the second load comprises a set of bitcells.

Aspect 15: A method of driving a load, comprising: supplying a first current to the load using a flipped voltage follower; and drawing a second current from the load using a source follower.

Aspect 16: The method of aspect 15, wherein the first and second currents include transient currents.

Aspect 17: The method of aspect 15 or 16, wherein the flipped voltage follower and the source follower are coupled in parallel.

Aspect 18: The method of any one of aspects 15-17, wherein the flipped voltage follower and the source follower are both coupled between an upper voltage rail and a lower voltage rail, have a common input configured to receive an input signal, and a common output coupled to the load.

Aspect 19: The method of any one of aspects 15-18, wherein the load comprises a set of bitcells, wherein supplying the first current to the load is in response to increasing a number of the set of bitcells coupled to the flipped voltage follower.

Aspect 20: The method of any one of aspects 15-19, wherein the load comprises a set of bitcells, wherein drawing the second current from the load is in response to decreasing a number of the set of bitcells coupled to the source follower.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus, comprising:
a first amplifier, comprising:
a flipped voltage follower, and
a source follower coupled in parallel with the flipped voltage follower; and
a first load coupled to an output of the first amplifier.

2. The apparatus of claim 1, wherein the flipped voltage follower comprises:
a first p-channel field effect transistor (PFET) including a source coupled to an upper voltage rail;
a second PFET including a source coupled to a drain of the first PFET, a gate configured to receive an input signal, and a drain coupled to a gate of the first PFET, wherein the drain of the first PFET and the source of the second PFET serve as the output of the first amplifier; and
a first current source coupled between a drain of the second PFET and a lower voltage rail.

3. The apparatus of claim 2, wherein the source follower comprises:
a second current source coupled between the upper voltage rail and the output of the first amplifier; and
a third PFET including a source coupled to the output of the first amplifier, a gate coupled to the gate of the second PFET, and a drain coupled to the lower voltage rail.

4. The apparatus of claim 1, wherein the flipped voltage follower comprises:
a first current source;
a first NFET, wherein the first current source is coupled between an upper voltage rail and a drain of the first NFET; and
a second NFET including a drain coupled to a source of the first NFET, a gate coupled to the drain of the first NFET, and a source coupled to a lower voltage rail, wherein the source of the first NFET and the drain of the second NFET serve as the output of the first amplifier.

5. The apparatus of claim 4, wherein the source follower comprises:
a third NFET including a drain coupled to the upper voltage rail, a gate coupled to the gate of the first NFET, and a source coupled to the output of the first amplifier; and
a second current source coupled between the output of the first amplifier and the lower voltage rail.

6. The apparatus of claim 1, wherein the first load comprises a load driver.

7. The apparatus of claim 6, wherein the load driver comprises:
a p-channel field effect transistor (PFET) including a source coupled to an upper voltage rail, and a gate coupled to the output of the first amplifier, and
a second load coupled between a drain of the PFET and a lower voltage rail.

8. The apparatus of claim 7, further comprising a second amplifier including a first input configured to receive a reference voltage, a second input coupled to a node between the PFET and the second load, and an output coupled to an input of the first amplifier.

9. The apparatus of claim 7, wherein the second load comprises a set of bitcells.

10. The apparatus of claim 1, wherein the first load comprises:
a replica load driver; and
a set of load drivers.

11. The apparatus of claim 10, wherein the replica load driver comprises:
a replica p-channel field effect transistor (PFET) including a source coupled to an upper voltage rail, and a gate coupled to the output of the first amplifier, and
a replica load coupled between a drain of the replica PFET and a lower voltage rail.

12. The apparatus of claim 11, further comprising a second amplifier including a first input configured to receive a reference voltage, a second input coupled to a node between the replica PFET and the replica load, and an output coupled to an input of the first amplifier.

13. The apparatus of claim 12, wherein each of the set of load drivers comprises:
a PFET including a source coupled to the upper voltage rail;
a second load coupled between a drain of the PFET and the lower voltage rail; and
a switching device including a pole terminal coupled to a gate of the PFET, a first throw terminal coupled to the output of the first amplifier, and a second throw terminal coupled to the lower voltage rail or ground.

14. The apparatus of claim 13, wherein:
the replica load comprises a set of replica bitcells; and
the second load comprises a set of bitcells.

15. A method of driving a load, comprising:
supplying a first current to the load using a flipped voltage follower; and
drawing a second current from the load using a source follower.

16. The method of claim 15, wherein the first and second currents include transient currents.

17. The method of claim 15, wherein the flipped voltage follower and the source follower are coupled in parallel.

18. The method of claim 15, wherein the flipped voltage follower and the source follower are both coupled between an upper voltage rail and a lower voltage rail, have a common input configured to receive an input signal, and a common output coupled to the load.

19. The method of claim 15, wherein the load comprises a set of bitcells, wherein supplying the first current to the load is in response to increasing a number of the set of bitcells coupled to the flipped voltage follower.

20. The method of claim 15, wherein the load comprises a set of bitcells, wherein drawing the second current from the load is in response to decreasing a number of the set of bitcells coupled to the source follower.
